(19) United States
(12) Patent Application Publication
(10) Pub. No.: US 2025/0228053 A1
(43) Pub. Date: Jul. 10, 2025

(54) DISPLAY PANEL AND DISPLAY APPARATUS

(71) Applicant: KunShan Go-Visionox Opto-Electronics Co., Ltd, Kunshan (CN)

(72) Inventors: Junhui LOU, Kunshan (CN); Xu QIN, Kunshan (CN); Pengle DANG, Kunshan (CN); Lin GE, Kunshan (CN); Zeshang HE, Kunshan (CN)

(73) Assignee: KunShan Go-Visionox Opto-Electronics Co., Ltd, Kunshan (CN)

(21) Appl. No.: 19/093,281

(22) Filed: Mar. 28, 2025

Related U.S. Application Data
(63) Continuation of application No. PCT/CN2022/130236, filed on Nov. 7, 2022.

(30) Foreign Application Priority Data
Sep. 30, 2022 (CN) 202211215409.6

(51) Int. Cl. H10H 29/49

(52) U.S. Cl. CPC H10H 29/49

(57) ABSTRACT

The present application provides a display panel and a display apparatus, the display panel has a first region and a second region, a transmittance of the first region is greater than a transmittance of the second region, and the display panel includes a first pixel unit, at least one first pixel circuit and at least one first signal line. The first pixel unit is arranged in the first region, the at least one first pixel circuit is located in the second region and located on a side of the first region along a second direction, the at least one first pixel circuit is connected to the first pixel unit. The at least one first signal line is connected to the first pixel circuit corresponding to the first pixel unit.

### CROSS-REFERENCE TO RELATED APPLICATION

The present application claims priority to Chinese Patent Application No. 202211215409.6 filed on Sep. 30, 2022, and titled “DISPLAY PANEL AND DISPLAY APPARATUS”, which is incorporated herein by reference in its entirety.

### FIELD

The present application relates to the field of display devices, and in particular, to a display panel and a display apparatus.

### BACKGROUND

With the rapid development of electronic devices, demands of users for the screen-to-body ratio are higher and higher, resulting in that the full-screen display of the electronic devices attracts more and more attention in the industry.

In order to achieve different functions of the display panel, it is necessary to integrate components such as a front camera, a telephone receiver, an infrared sensing element and the like in a photosensitive region of the display panel. In order to achieve a full-screen display effect, it is necessary to arrange a pixel structure in the photosensitive region. However, due to the limitation of the photosensitive region, the layout of the lines connected to the pixel structure is affected, and the display panel is prone to a problem such as a non-uniform display.

### SUMMARY

Embodiments of the present application provide a display panel and a display apparatus, which can improve display reliability.

The embodiments of the present application provide a display panel having a first region and a second region, a transmittance of the first region is greater than a transmittance of the second region, and the display panel includes a pixel unit, at least one first pixel circuit and at least one first signal line. The first pixel unit is at least partially arranged in the first region, the at least one first pixel circuit is located in the second region and located on a side of the first region along a second direction, and the at least one first pixel circuit is connected to the first pixel unit. The at least one first signal line is connected to the first pixel circuit corresponding to the first pixel unit, the at least one first signal line includes a main body segment extending along a first direction, and a first branch and a second branch branched from one end of the main body segment, the first branch is connected to the first pixel circuit, the second branch includes a first segment arranged in the second region, the first segment and the main body segment are located respectively on two sides of the first region, and the first direction intersects the second direction.

In a second aspect, the embodiments of the present application provide a display apparatus including the display panel according to any of the previous implementations.

The embodiments of the present application provide the display panel and the display apparatus, and the first signal line includes the first branch and the second branch. By arranging a branch structure, an overall extension length of the first signal line is reduced, a duration of the first signal line charging and discharging the first pixel circuit is reduced, and the risk of non-uniform display of the display panel is reduced, to improve the display reliability.

### BRIEF DESCRIPTION OF THE DRAWINGS

FIG. 1 is a schematic top view of a display panel according to embodiments of the present disclosure;

FIG. 2 is a partial enlarged schematic structural view of a region Q in FIG. 1;

FIG. 3 is a partial enlarged schematic structural view of a region Q in FIG. 1 in another example;

FIG. 4 is a simplified view of a connection structure of a single first pixel circuit and a single pixel unit in a display panel according to embodiments of the present disclosure;

FIG. 5 is a simplified view of a connection structure of a single first pixel circuit and a single pixel unit in another display panel according to embodiments of the present disclosure;

FIG. 6 is a simplified view of a connection structure of a single first pixel circuit and a single pixel unit in yet another display panel according to embodiments of the present disclosure;

FIG. 7 is a simplified view of a connection structure of a single first pixel circuit and a single pixel unit in yet another display panel according to embodiments of the present disclosure;

FIG. 8 is a simplified view of a connection structure of a single first pixel circuit and a single pixel unit in yet another display panel according to embodiments of the present disclosure;

FIG. 9 is a simplified view of a connection structure of a single first pixel circuit and a single pixel unit in yet another display panel according to embodiments of the present disclosure;

FIG. 10 is a simplified view of a connection structure of a single first pixel circuit and a single pixel unit in yet another display panel according to embodiments of the present disclosure;

FIG. 11 is a simplified view of a connection structure of a single first pixel circuit and a single pixel unit in yet another display panel according to embodiments of the present disclosure;

FIG. 12 is a simplified view of a connection structure of a single first pixel circuit 20 and a single pixel unit in yet another display panel according to embodiments of the present disclosure;

FIG. 13 is a schematic structural view of a display apparatus according to embodiments of the present disclosure.

### DETAILED DESCRIPTION

Implementations of the present application are described in further detail below with reference to the drawings and embodiments. The detailed description and drawings of the following embodiments are used to exemplarily illustrate the principles of the present application instead of limiting the scope of the present application. That is, the present application is not limited to the described embodiments.

In a display panel, a photosensitive region in the display panel needs to have a relatively great transmittance due to the presence of an element such as a front camera, and in order to increase the transmittance of the photosensitive region, a pixel circuit configured to drive a pixel unit in the photosensitive region to emit light is usually arranged outside the photosensitive region. However, such design increases an extension length corresponding to a line connected to the pixel circuit, resulting in a problem such as a non-uniform display of the display panel.

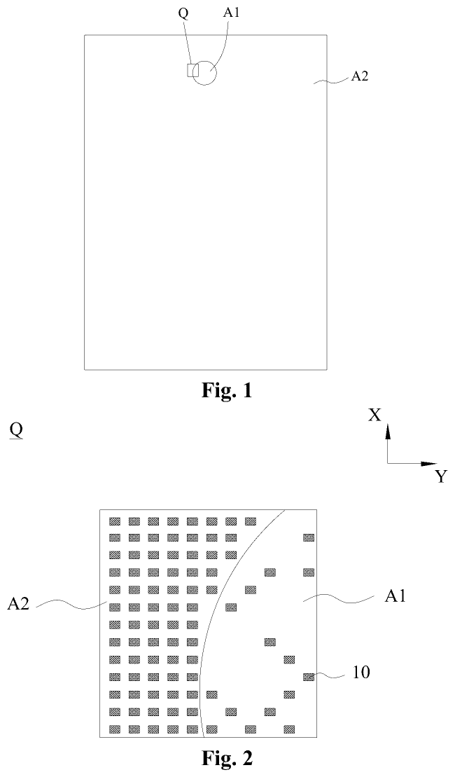

In order to solve the above problem, embodiments of the present disclosure provide a display panel. Referring to FIG. 1 to FIG. 4, the display panel has a first region A1 and a second region A2, a transmittance of the first region A1 is greater than a transmittance of the second region A2, and the display panel includes a plurality of first pixel units 10, a plurality of first pixel circuits 20 and a plurality of first signal lines 30. The first pixel units 10 are arranged in the first region A1, the first pixel circuits 20 are located in the second region A2 and located on a side of the first region A1 along a second direction, and the first pixel circuits 20 are correspondingly connected to the first pixel unit 10. The first signal line 30 is connected to the first pixel circuit 20 corresponding to the first pixel unit 10 arranged in the second region A2, the first signal line 30 includes a main body segment 31 extending along a first direction X, and a first branch 32 and a second branch 33 branched from one end of the main body segment 31 the first branch 32 is connected to the first pixel circuit 20, the second branch 33 includes a first segment 331 arranged in the second region A2, the first segment 331 and the main body segment 31 are located respectively on two sides of the first region A1, and the first direction X intersects the second direction Y.

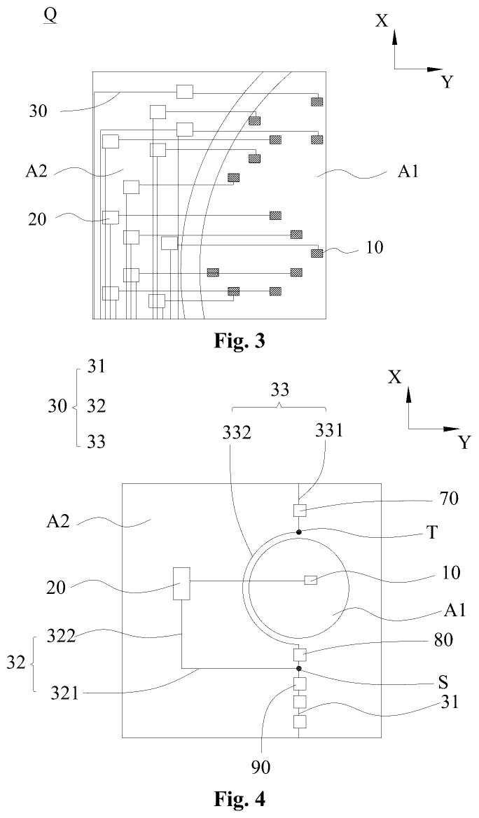

FIG. 1 shows a schematic top view of a display panel according to an embodiment of the present disclosure, FIG. 2 is a partial enlarged schematic structural view of a region Q in FIG. 1, FIG. 3 is a partial enlarged schematic structural view of a region Q in FIG. 1 in another example, and FIG. 4 is a simplified view of a connection structure of a single first pixel circuit 20 and a single pixel unit 10. FIG. 3 and FIG. 2 show different layer structures, FIG. 2 shows an arrangement of the first pixel units 10 at the region Q, and FIG. 3 differs from FIG. 2 in that FIG. 3 shows an arrangement structure of the first pixel circuits 20, and the first pixel units 10 in the first region A1 are maintained in FIG. 3.

The display panel has at least two regions, the first region A1 and the second region A2, the first region A1 is a photosensitive region of the display panel, a photosensitive element (not shown) is arranged in the first region A1, and the photosensitive element includes, but is not limited to, components such as a front camera, a telephone receiver, an infrared sensing element and the like. At the same time, the first pixel unit 10 is further arranged in the first region A1, and the first region A1 can achieve a display function, to meet the needs of full-screen. The shape of the first region A1 is not limited in the embodiments of the present disclosure. The outline of the first region A1 may be a circular shape, a square shape, a polygonal shape, a water-dropped shape, or the like.

The second region A2 is arranged around an outer circumference of the first region A1, and the second region A2 is a normal display region of the display panel, that is, the pixel unit is also arranged in the second region A2. Generally, in order to achieve a photosensitive function of the first region A1, the transmittance of the first region A1 is set to be greater than the transmittance of the second region A2. In an example, a density of the first pixel units 10 in the first region A1 may be reduced appropriately to increase the transmittance of the first region A1; or a size of the first pixel unit 10 in the first region A1 may be reduced to increase the transmittance of the first region A1. In the implementation, the second region A2 is arranged around the outer circumference of the first region A1, and the second region A2 may be arranged completely or partially around the first region A1.

The first pixel circuits 20 are configured to drive the first pixel units 10 in the first region A1 to achieve a light-emitting function, and the structure of the first pixel circuit 20 is not limited in the embodiments of the present disclosure. In an example, the first pixel circuit 20 may take the form of 7T1C, 8T1C, or the like. Since arranging the first pixel circuits 20 in the first region A1 may reduce the transmittance of the first region A1, the first pixel circuits 20 are arranged in the second region A2 and on a side of the first region A1 along the second direction Y in the embodiments of the present disclosure. That is, the arrangement of the first pixel circuits 20 does not have an effect on the transmittance of the first region A1, and a better photosensitive effect in the first region A1 can be achieved.

The first signal lines 30 are connected to the first pixel circuits 20, the first signal lines 30 can transmit corresponding driving signals to the first pixel circuits 20 and drive the first pixel units 10 located in the first region A1 by the first pixel circuits 20 to achieve the light-emitting function. The particular type of the first signal line 30 is not limited in the embodiments of the present disclosure.

The first signal line 30 includes the main body segment 31 extending along the first direction X, and the first direction X intersects the second direction Y. In an example, the first direction X is perpendicular to the second direction Y. The extension of the main body segment 31 along the first direction X mentioned in the embodiments of the present disclosure means that the main body segment 31 has a certain extension distance along the first direction X, and all of extension directions of the main body segment 31 at various locations may be the first direction X, or a part of the extension directions of the main body segment 31 may be the direction X, and other part of the extension directions of the main body segment 31 may be inclined relative to the first direction X. The main body segment 31 itself may be a structure other than a straight line, for example, a structure such as a curved line, or a structure with a part of it being a straight line and other parts of it being a curved line.

The main body segment 31 is at least partially located on a side of the first region A1 along the first direction X. In the related art, since the first pixel circuit 20 is located on a side of the first region A1 along the second direction Y, the main body segment 31 may then continue to extend along the first direction X and the second direction Y to connect to the first pixel circuit 20 and cross the other side of the first region A1 along the first direction X. Such design may result in an increase in an overall extension length of the first signal line 30, the increase in the extension length may cause additional resistance and capacitance, and thus a duration of the first signal line 30 charging and discharging the first pixel circuit 20 is increased, and a problem such as a non-uniform display may be caused easily.

However, in the embodiments of the present disclosure, two branches, a first branch 32 and a second branch 33, are branched from one end of the main body segment 31, the first branch 32 is configured to connect to the first pixel circuit 20, the second branch 33 includes a first segment 331, and the first segment 331 and the main body segment 31 are located respectively on two sides of the first region A1. “The first segment 331 and the main body segment 31 are located respectively on two sides of the first region A1” mentioned in the embodiments of the present disclosure means that: the first segment 331 and the main body segment 31 are separated by the first region A1, and the first segment 331 and the main body segment 31 may be located on the same straight line parallel to the first direction X or may be located on different straight lines, that is, the first segment 331 and the main body segment 31 are staggered with each other, which is not limited in the embodiments of the present disclosure.

It may be known from the first segment 331 and the main body segment 31 being located respectively on two sides of the first region A1 that the second branch 33 crosses the first region A1 along the first direction X and cannot be connected to the first pixel circuit 20 connected to the first branch 32. Compared to the scheme in the related art in which the first signal line 30 is wound and connected to the corresponding first pixel circuit 20 and then continuously extended from the first pixel circuit 20 to connect to other first pixel circuits 20 to cross the first region A1 along the first direction X, the design of the first branch 32 and the second branch 33 in the embodiments of the present disclosure can effectively reduce a total extension length of the first signal line 30.

It should be noted that the total extension length of the first signal line 30 mentioned in the embodiments of the present disclosure refers to a sum of extension lengths of various parts of the first signal line 30. Specifically, the total extension length of the first signal line 30 in the embodiments of the present disclosure at least includes a sum of an extension length of the main body segment 31, an extension length of the first branch 32 and an extension length of the second branch 33.

In addition, the main body segment 31 may be completely located on a side of the first region A1 along the first direction X, or may be partially located on a side of the first region A1 along the first direction X and partially located on a side of the first pixel circuit 20 facing the first region A1, which is not limited in the embodiments of the present disclosure.

The first signal line 30 in the embodiments of the present disclosure includes the first branch 32 and the second branch 33. By arranging the branch structure, the overall extension length of the first signal line 30 is reduced, a duration of the first signal line 30 charging and discharging the first pixel circuit 20 is reduced, and the risk of non-uniform display of the display panel is reduced, to improve the display reliability.

It should be noted that, in addition to being connected to the first pixel circuits 20, the first signal lines 30 may be connected to a plurality of other pixel circuits at the same time, which is not limited in the embodiments of the present disclosure.

In some embodiments, as shown in FIG. 4, the second branch 33 includes the first segment 331 and a second segment 332 connected to the first segment 331 and the main body segment 31, the first segment 331 and the main body segment 31 are located on two sides of the first region A1 along the first direction X, and the first segment 331 intersects the second segment 332 at an intersection point T. FIG. 4 is a simplified schematic view, and in the actual line design of the display panel, the intersection point T may be equivalent to the location of the third pixel circuit 70.

Most of the structure of the main body segment 31 is located on one side of the first region A1 along the first direction X, the first segment 331 is located on the other side of the first region A1 along the first direction X, and the first segment 331 may also be formed extending along the first direction X. The second segment 332 has two opposite ends along the first direction X, one of the ends is connected to the first segment 331, and the other of the ends is connected to the main body segment 31.

It should be noted that the material and the specific line layout of the second segment 332 are not limited in embodiments of the present disclosure. In an example, the material of the second segment 332 may be the same as the material of the first segment 331 or may be different from the material of the first segment 331. In the second region A2, the second segment 332 may be arranged extending around the first region A1 or may be arranged extending through the first region A1.

In some embodiments, as shown in FIG. 4, the display panel further includes a third pixel circuit 70 as well as a fourth pixel circuit 80 and a plurality of fifth pixel circuits 90 located on two sides of the first region A1 along the first direction X, the third pixel circuit 70 is connected to the first segment 331, the fourth pixel circuit 80 and the fifth pixel circuits 90 are connected to the main body segment 31, and the third pixel circuit 70, the fourth pixel circuit 80 and the fifth pixel circuits 90 are arranged in a line along the first direction X.

In addition to being connected to the first pixel circuit 20, a single first signal line 30 can be configured to connect to the third pixel circuit 70, the fourth pixel circuit 80 and the plurality of fifth pixel circuits 90, and the number of the fifth pixel circuits 90 is not limited in the embodiments of the present disclosure.

The fourth pixel circuit 80 and the fifth pixel circuits 90 are located on the same side of the first region A1, and the third pixel circuit 70 is located on the other side of the first region A1. The third pixel circuit 70, the fourth pixel circuit 80 and the fifth pixel circuits 90 are arranged in the same straight line, and signals on the first signal line 30 can be transmitted to the third pixel circuit 70, the fourth pixel circuit 80 and the fifth pixel circuits 90 together to drive pixel units corresponding to the third pixel circuit 70, the fourth pixel circuit 80 and the fifth pixel circuits 90 to emit light. It should be noted that the pixel units corresponding to the third pixel circuit 70, the fourth pixel circuit 80, and the fifth pixel circuits 90 are located in the second region A2.

In some embodiments, as shown in FIG. 4, a connection point S of the main body segment 31 and the first branch 32 is located on a side of the first region A1 along the first direction X.

In the embodiments of the present disclosure, the main body segment 31 is completely located on a side of the first region A1 along the first direction X. In an example, referring to FIG. 4, one end of the main body segment 31 is located at the bottom of the display panel and continues to extend towards the first region A1 along the first direction X until it extends close to the first region A1, then two branch structures, the first branch 32 and the second branch 33, are branched from the main body segment 31, the first branch 32 is directly connected to the first pixel circuit 20, and the second branch 33 bypasses the first region A1 and extends to the top of the display panel.

Further, in some embodiments, the first branch 32 includes a first branch segment 321 extending along the second direction Y and connected to the main body segment 31, and a second branch segment 322 extending along the first direction X and connected to the first branch segment 321 and the first pixel circuit 20.

Since the connection point S of the main body segment 31 and the first branch 32 is staggered with the first pixel circuit 20, and there is a staggered distance along both the first direction X and the second direction Y, the first branch 32 is provided with the first branch segment 321 and the second branch segment 322 in the embodiments of the present disclosure. The first branch segment 321 extends from the connection point S to a location corresponding to the first pixel circuit 20 in the second direction Y, and the second branch segment 322 extends from the first pixel circuit 20 to a location corresponding to the first pixel circuit 20 in the first direction X to meet the first branch segment 321.

It should be noted that, in addition to the first branch segment 321 and the second branch segment 322, the first branch 32 may include other branch segments, which need to be specifically determined according to the layout of the internal structure of the display panel. Further, similar to the main body segment 31, at least one of the first branch segment 321 and the second branch segment 322 may be a structure other than a straight line, for example, a structure such as a curved line, or even a structure with a part being a straight line and a part being a curved line, as long as the overall extension tendency of the first branch segment 321 is the second direction Y and the overall extension tendency of the second branch 322 is the first direction X.

In some embodiments, the connection point S of the main body segment 31 and the first branch 32, and the first region A1 are located on the same side of the first pixel circuit 20 along the second direction Y. One part of the main body segment 31 is located on a side of the first region A1 along the first direction X, the other part is located on a side of the first pixel circuit 20 close to the first region A1, and the part of the main body segment 31 located on the side of the first pixel circuit 20 close to the first region A1 may be located in the first region A1, or may be located between the first region A1 and the first pixel circuit 20, which is not limited in the embodiments of the present disclosure.

In the embodiments of the present disclosure, since the connection point S of the main body segment 31 and the first branch 32 is located on a side of the first pixel circuit 20 close to the first region A1 along the second direction Y, the first branch 32 may extend only along the second direction Y to achieve the connection with the first pixel circuit 20, that is, the second branch segment of the first branch 32 may be removed and the connection with the first pixel circuit 20 may be achieved only by the first branch segment. Such design can simplify the structure of the first branch 32 and reduce the extension length of the first branch 32, further reducing the risk of non-uniform display of the display panel.

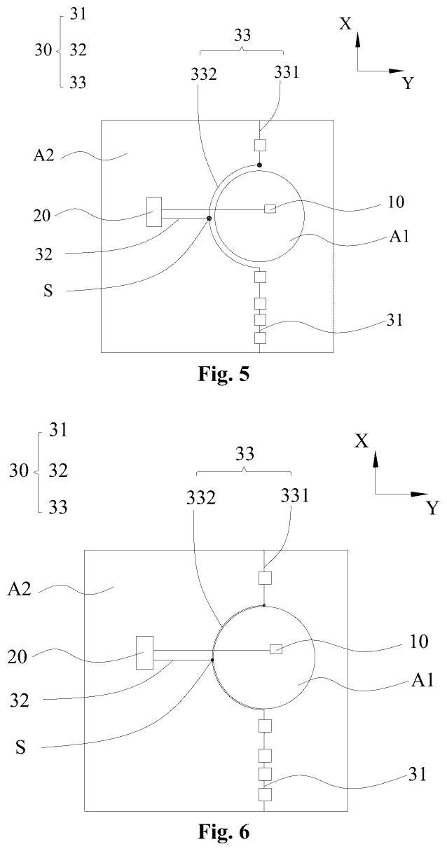

In some embodiments, as shown in FIG. 4 and FIG. 5, the second segment 332 extends around an outer circumference of the first region A1.

The second segment 332 is connected to the first segment 331 and the main body segment 31, and the second segment 332 is located in the second region A2. On this basis, in the embodiments of the present disclosure, the second segment 332 extends around the outer circumference of the first region A1, in other words, the second segment 332 is arranged close to the first region A1 and the shape of the second segment 332 matches the shape of the outline of the first region A1. Further, referring to FIG. 6, the second segment 332 may be arranged abutting against an edge of the first region A1. Compared to other line patterns of the second segment 332 in the second region A2, such design can greatly reduce the extension length of the second segment 332, and the overall extension length of the first signal line 30 is reduced, the risk of non-uniform display is reduced, and the display reliability is improved.

In some embodiments, the first region A1 is a circular structure, and the second segment 332 includes an arc-shaped segment.

Under a condition that the first region A1 is the circular structure, in order to make the shape of the second segment 332 to be matched more with the circular structure, in the embodiments of the present disclosure, the arc-shaped segment is arranged in the second segment 332, and the arc-shaped segment can be matched more with the external outline of the first region A1, to effectively reduce the length of the second segment 332. It should be noted that, under a condition that the connection point of the main body segment 31 and the first branch 32 is located on a side of the first pixel circuit 20 close to the first region A1 along the second direction Y, the main body segment 31 may include an arc-shaped segment, and the arc-shaped segment extends around the outer circumference of the first region A1, to reduce the extension length of the main body segment 31.

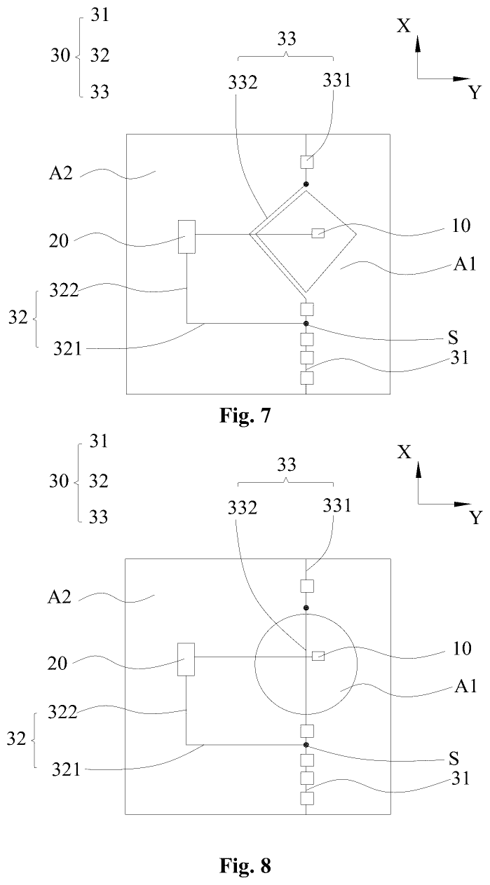

In some embodiments, referring to FIG. 7, the first region A1 is a polygonal structure, and the second segment 332 includes a bending segment. The polygonal structure may be a triangle, a quadrilateral, a pentagon, or the like.

Under a condition that the first region A1 is the polygonal structure, in order to make the shape of the second segment 332 to be matched more with the polygonal structure, in the embodiments of the present disclosure, the bending segment is arranged in the second segment 332, and the bending segment can be matched more with the external outline of the first region A1, to effectively reduce the length of the second segment 332. It should be noted that, under a condition that the connection point of the main body segment 31 and the first branch 32 is located on a side of the first pixel circuit 20 close to the first region A1 along the second direction Y, the main body segment 31 may include an bending segment, and the bending segment extends around the outer circumference of the first region A1, to reduce the extension length of the main body segment 31.

In some embodiments, referring to FIG. 8, the second segment 332 is located in the first region A1.

The second segment 332 is configured to connect the main body segment 31 and the first segment 331, and the second segment 332 is arranged in the first region A1, and the risk of unnecessary winding of the second segment 332 is reduced, and the length of the second segment 332 is reduced, to further reduce the overall length of the first signal line 30. In an example, the second segment 332 is a straight line structure, and the extension length of the second segment 332 is further reduced.

In this embodiment, the second segment 332 is a transparent structure.

Since the second segment 332 is located in the first region A1, the presence of the second segment 332 may have an effect on the transmittance of the display panel in the first region A1. On this basis, in the embodiment of the present disclosure, the second segment 332 is the transparent structure, and the transparent structure itself has a relatively small effect on the transmittance of the display panel, that is, such design can reduce the effect of the second segment 332 on the transmittance of the first region A1, and under a condition that the transmittance of the first region A1 is satisfied, the extension length of the second segment 332 is further reduced, and the display reliability of the display panel is improved.

It should be noted that the material of the second segment 332 may be or may not be the same as the materials of at least a part of the structures of the first segment 331 or the main body segment 31. In an example, the first segment 331 and the main body segment 31 both include metallic conductive materials, and the second segment 332 includes at least one of indium tin oxide (ITO), indium zinc oxide, silver doped indium tin oxide, and silver doped indium zinc oxide.

In some embodiments, as shown in FIG. 8, the second segment 332 extends along the first direction X. In the embodiments of the present disclosure, the second segment 332 extending along the first direction X means that the overall extension tendency of the second segment 332 is along the first direction X, and the second segment 332 itself may be a straight line structure, a curved line structure or other structures, which is not limited in the embodiments of the present disclosure.

It may be known from the foregoing that the main body segment 31 extends along the first direction X, the first segment 331 is located on a side of the first region A1 away from the main body segment 31. On this basis, in order to achieve the connection between the first segment 331 and the main body segment 31 by the second segment 332 and reduce the extension length of the second segment 332 as much as possible, in the embodiments of the present disclosure, the second segment 332 is arranged in the first region A1 and formed as extending along the first direction X. Such design reduces the extension length of the second segment 332 to the greatest extent, and reduces the risk of non-uniform display of the display panel. In one embodiment, the second segment 332 passes straight through the first region A1 along the first direction X.

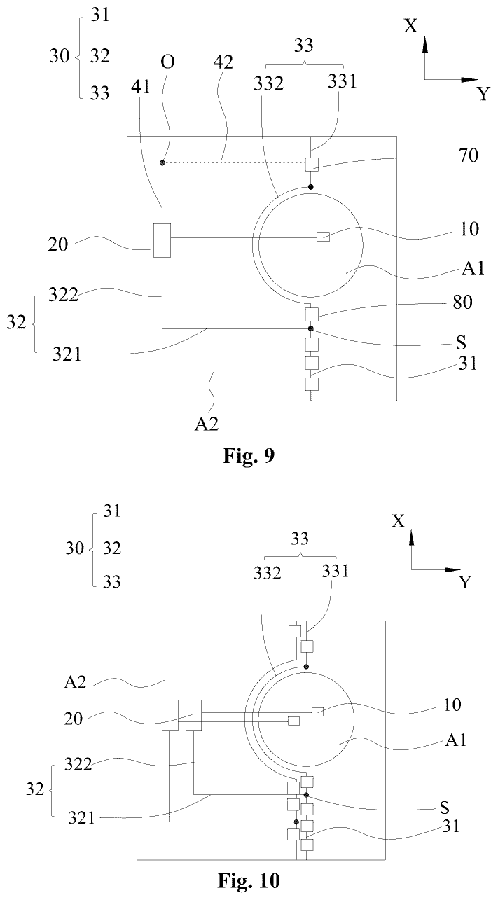

In some embodiments, referring to FIG. 9, a first virtual extension line 41 extending along the first direction X and passing through the first pixel circuit 20 intersects a second virtual extension line 42 extending along the second direction Y and passing through the third pixel circuit 70 at a virtual intersection point O. A sum of a distance from the first pixel circuit 20 to the virtual intersection point O and a distance from the third pixel circuit 70 to the virtual intersection point O is greater than an extension length from the third pixel circuit 70 to the fourth pixel circuit 80 in the second segment 332.

The first virtual extension line 41 and the second virtual extension line 42 are both assumed line segment structures extending along the first direction X and the second direction Y, respectively, and intersecting at the virtual intersection point O. The distance from the first pixel circuit 20 to the virtual intersection point O is a length of the first virtual extension line 41, and the distance from the third pixel circuit 70 to the virtual intersection point O is a length of the second virtual extension line 42.

In the related art, a conductive line structure is arranged at the location of the first virtual extension line 41 and the second virtual extension line 42 in the display panel, to form a corresponding signal line connected to the first pixel circuit 20. Specifically referring to FIG. 8, the signal line connected to the first pixel circuit 20 generally includes the main body segment 31, the first branch 32 connecting the main body segment 31 and the first pixel circuit 20, a conductive line structure connecting the first pixel circuit 20 and the third pixel circuit 70 and extending along a path of the first virtual extension line 41 and the second virtual extension line 42, the first segment 331, and a conductive line structure connecting the first segment 331 and the fourth pixel circuit 80.

In the embodiments of the present disclosure, however, the first signal line 30 connected to the first pixel circuit 20 includes the main body segment 31 as well as the first branch 32 and the second branch 33 branched from one end of the main body segment 31, and the second branch 33 includes the first segment 331 located on a side of the first region A1 away from the main body segment 31, and the second segment 332 connecting the first segment 331 and the main body segment 31.

In summary, compared to the corresponding signal line connected to the first pixel circuit 20 in the related art, in the first signal line 30 in the embodiments of the present disclosure, a part connected to the third pixel circuit 70 and the fourth pixel circuit 80 in the second segment 332 is added, but the conductive line structure connected to the first pixel circuit 20 and extending along the path of the first virtual extension line 41 and the second virtual extension line 42 is deleted. Accordingly, on this basis, by controlling that the extension length of the second segment 332 is less than a sum of the extension length of the first virtual extension line 41 and the extension length of the second virtual extension line 42, the extension length of the first signal line 30 in the embodiments of the present disclosure is less than the extension length of the corresponding signal line connected to the first pixel circuit 20 in the related art, and thus, compared to the related art, the display panel according to the embodiments of the present disclosure is less prone to the problem such as the non-uniform display, and the service life of the display panel is improved.

In some embodiments, a spacing between the first region A1 and the first pixel circuit 20 is not less than 2 mm.

It may be understood that, the greater the spacing between the first region A1 and the first pixel circuit 20 is, the greater the extension length of the corresponding second virtual extension line is, but the extension length of the second segment 332 is not affected by the spacing between the first region A1 and the first pixel circuit 20. Further, the greater the spacing between the first region A1 and the first pixel circuit 20 is, the greater a difference between the extension length of the first signal line 30 in the embodiments of the present disclosure and the extension length of the corresponding signal line connected to the first pixel circuit 20 in the related art. Under this condition, the risk of non-uniform display of the display panel according to the embodiments of the present disclosure can be further reduced, and the display reliability of the display panel can be improved.

In some embodiments, referring to FIG. 10, the display panel includes a plurality of first signal lines 30.

Generally, the first region A1 includes a plurality of the first pixel units 10, and the display panel includes a plurality of first signal lines 30 and a plurality of first pixel circuits 20 corresponding to the first pixel units 10. The plurality of first pixel circuits 20 are arranged along the second direction Y and connected to the plurality of first signal lines 30, and a light emission control of the plurality of first pixel units 10 located in the first region A1 is achieved.

It should be noted that the numbers of the first pixel circuits 20 and the first pixel units 10 may be the same or different. Specifically, the plurality of first pixel units 10 located in the first region A1 and the plurality of first pixel circuits 20 may be in a one-to-one correspondence, or one first pixel circuit 20 may drive a plurality of first pixel units 10 to emit light at the same time, to reduce an arrangement density of the first pixel circuits 20, which is not limited in the embodiments of the present disclosure.

In some embodiments, on a surface perpendicular to a thickness direction of the display panel, orthographic projections of second segments 332 of the plurality of first signal lines 30 at least partially overlap with one another.

The thickness direction of the display panel mentioned in the embodiments of the present disclosure refers to a stacked direction of a plurality of film layers in the display panel, that is, the plurality of film layers in the display panel are stacked in sequence along the thickness direction of the display panel. Further, the surface perpendicular to the thickness direction of the display panel mentioned in the embodiments of the present disclosure refers to any plane perpendicular to the thickness direction of the display panel.

The second segment 332 is configured to connect the first segment 331 and the main body segment 31. The second segment 332 may be located in the second region A2 and may be arranged extending around the outer circumference of the first region A1, or the second segment 332 may be located in the first region A1. On this basis, in the embodiments of the present disclosure, different first signal lines 30 are arranged in different film layers, and the orthographic projections of the second segments 332 of the plurality of first signal lines 30 at least partially overlap with one another, and a line density near the first region A1 or the outer circumference of the first region A1 can be reduced.

Specifically, under a condition that the second segment 332 is located in the first region A1, and the orthographic projections of the second segments 332 of the plurality of first signal lines 30 at least partially overlap with one another, the effect of the second segment 332 on the transmittance of the first region A1 can be reduced, to improve the photosensitive effect of the display panel. Under a condition that the second segment 332 is located in the second region A2 and arranged extending around the outer circumference of the first region A1, and the orthographic projections of the second segments 332 of the plurality of first signal lines 30 at least partially overlap with one another, a line density around the first region A1 can be reduced, to reduce the risk of obvious shadows occurring around the circumference of the first region A1 and improving the display effect of the display panel.

In some embodiments, the orthographic projections of the second segments 332 of the plurality of first signal lines 30 along the thickness direction of the display panel are arranged side by side along the second direction Y.

In the embodiments of the present disclosure, the plurality of first signal lines 30 may be located on the same film layer or may be located on different film layers. Orthographic projections of the plurality of first signal lines 30 are arranged side by side along the second direction Y, and under a condition that the plurality of first signal lines 30 are located on the same film layer, an insulation material is sandwiched between adjacent first signal lines 30 to insulate the adjacent first signal lines 30 from each other.

In summary, the second segments 332 of the plurality of first signal lines 30 in the embodiments of the present disclosure may overlap with one another or may be arranged side by side with each other on the surface perpendicular to the thickness direction of the display panel, and the specific arrangement may be designed according to the actual film layer structure of the display panel.

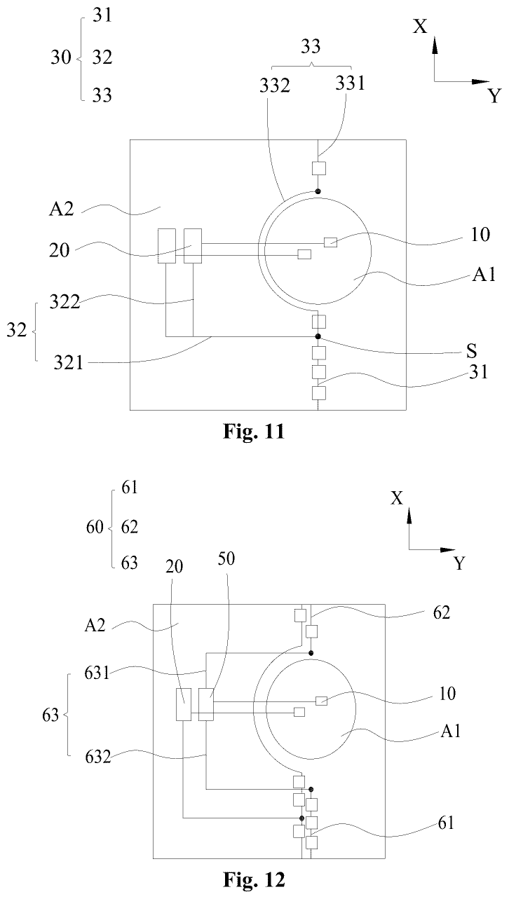

In some embodiments, referring to FIG. 11, the display panel includes a plurality of first pixel circuits 20, and the same first signal line 30 is connected the plurality of the first pixel circuits 20.

In the embodiment, the same first signal line 30 may be connected to the plurality of first pixel circuits 20, such design can reduce the number of the first signal lines 30, and a space in the second region A2 occupied by the first signal line 30 is reduced, and more first pixel units 10 are arranged in the second region A2 to achieve a better display effect.

In some embodiments, the first signal line 30 includes a plurality of first branches 32.

One first signal line 30 includes a plurality of first branches 32, and the plurality of first branches 32 are connected respectively to different first pixel circuits 20, and the total number of first signal lines 30 can be reduced, and the display effect of the display panel can be improved.

It should be noted that the plurality of first branches 32 of the single first signal line 30 may have parts overlapped with each other, that is, the plurality of first branches 32 may share a part of their structures for signal transmission. Or there may be no overlapped parts between the plurality of first branches 32, which is not limited in the embodiments of the present disclosure.

In some embodiments, the first signal line 30 is a data line, the data line extends along the first direction X, a scanning line extends along the second direction Y, and the plurality of first pixel circuits 20 are located on at least one side of the data line along the second direction Y. A connection direction of the first pixel circuit 20 and a corresponding first pixel unit 10 is the same as the second direction Y, and the second direction is a direction where a short side of the display panel extends along.

The data line and the scanning line intersecting with each other are arranged in the display panel, the data line extends along the first direction X and is configured to transmit a data signal, and the scanning line extends along the second direction Y and is configured to transmit a scanning signal. The data line and the scanning line are both configured to drive the first pixel units 10 in the first region A1 to emit light. A part of the data lines needs to be arranged across the first region A1, under this condition, the plurality of first pixel circuits 20 may be arranged on at least one side of the data line and arranged side by side along the second direction Y, the first branch of the data line can achieve an electrical connection between the data line and the first pixel circuit 20.

In one embodiment, the first signal line 30 may be the scanning line, under this condition, the scanning line extends along the first direction X, the data line extends along the second direction Y, and the plurality of first pixel circuits 20 are located on at least one side of the scanning line along the second direction Y. The connection direction of the first pixel circuit 20 and the corresponding first pixel unit 10 is parallel to the second direction Y, and the second direction is a direction where a long side of the display panel extends along.

Similar to the data line, a part of the scanning line needs to be arranged across the first region A1, under this condition, the plurality of first pixel circuits 20 may be arranged on at least one side of the scanning line and arranged side by side along the second direction Y, the first branch of the scanning line can achieve an electrical connection between the scanning line and the first pixel circuit 20.

In the above two embodiments, by adjusting the line pattern of at least one of the data line and the scanning line, the risk of non-uniform display of the display panel is reduced, and the display reliability is improved.

In some embodiments, referring to FIG. 4 and FIG. 12, the display panel further includes a second pixel circuit 50 and a second signal line 60, the second pixel circuit 50 is located in the second region A2 and located on a side of the first region A1 along the second direction Y, and the second pixel circuit 50 is connected to the first pixel unit 10 located in the first region A1. The second signal line 60 is connected to the second pixel circuit 50 corresponding to the first pixel unit 10 arranged in the first region A1, and the second signal line 60 includes a third segment 61 and a fourth segment 62 located on two sides of the first region A1 along the first direction X, as well as a fifth segment 63 connected to the third segment 61 and the fourth segment 62, and the fifth segment 63 is connected to the second pixel circuit 50.

The second pixel circuit 50 is similar to the first pixel circuit 20, both are configured to drive the first pixel units 10 in the first region A1 to achieve the light-emitting function, and the structure of the second pixel circuit 50 is not limited in the embodiments of the present disclosure. In an example, the second pixel circuit 50 may take the form of 7T1C, 8T1C or the like. The second signal lines 60 are connected to the second pixel circuits 50, and the second signal lines 60 can transmit corresponding driving signals to the second pixel circuits 50 and drive the first pixel units 10 located in the first region A1 by the second pixel circuits 50 to achieve the light-emitting function. The type of second signal line 60 is not limited in the embodiments of the present disclosure. In an example, the second signal line 60 is one of the data line and the scanning line.

The third segment 61 and the fourth segment 62 of the second signal line 60 are located respectively on two sides of the first region A1 along the first direction X, the fifth segment 63 is configured to connect the third segment 61 and the fourth segment 62, and the second pixel circuit 50 is located on an extending path of the fifth segment 63, and the fifth segment 63 can be connected to the second pixel circuit 50 at the same time. In an example, the fifth segment 63 includes a first sub-segment 631 electrically connected to the second pixel circuit 50 and the fourth segment 62, and a second sub-segment 632 electrically connected to the second pixel circuit 50 and the third segment 61.

In the embodiments of the present disclosure, the first pixel circuit 20 and the second pixel circuit 50 are both configured to drive the first pixel units 10 in the first region A1 to achieve the light-emitting function. For the difference in locations of the first pixel circuit 20 and the second pixel circuit 50, the first signal line 30 and the second signal line 60 are used respectively in the embodiments of the present disclosure to achieve a signal transmission. The second signal line 60 differs from the first signal line 30 in that the branch structure is not arranged on the second signal line 60, and an extension path of the second signal line 60 passes through the second pixel circuit 50, and the connection with the second pixel circuit 50 can be achieved. The differentiated design of the first signal line 30 and the second signal line 60 can satisfy connection requirements of the pixel circuits at different locations inside the display panel, to have a strong flexibility.

In some embodiments, the second pixel circuit 50 is located on a side of the first pixel circuit 20 close to the first region A1.

It may be known from the foregoing that the greater the distance between the first region A1 and the first pixel circuit 20 is, the greater the difference between the extension length of the first signal line 30 and the extension length of the corresponding signal line connected to the first pixel circuit 20 in the related art is, that is, the presence of the first signal line 30 may further reduce the risk of non-uniform display of the display panel.

However, for the second pixel circuit 50, since the connection with the second pixel circuit 50 is achieved using the second signal line 60, and in order to reduce the problem such as the non-uniform display of the display panel caused by the second signal line 60, in the embodiments of the present disclosure, the second pixel circuit 50 is arranged on a side of the first pixel circuit 20 close to the first region A1, to improve the display reliability of the display panel.

Specifically, it is assumed that the connection with the second pixel circuit 50 is achieved using the first signal line 30, compared to the connection achieved using the second signal line 60, the connection achieved using the first signal line 30 increases the length of a part of the structure of the second segment, but reduces the length of the first sub-segment 631. Further, since the second pixel circuit 50 is arranged closer to the first region A1 than the first pixel circuit 20, the length of the first sub-segment 631 of the second pixel circuit 50 is relatively small, and an extension length of the first sub-segment 631 is less than a length of the second segment corresponding to the second pixel circuit 50. Therefore, for the second pixel circuit 50, the risk of non-uniform display can be reduced and the display reliability can be improved by using the second signal line 60. In an example, a spacing between the first region A1 and the second pixel circuit 50 is not greater than 2 mm.

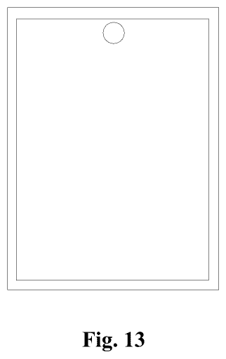

In a second aspect, referring to FIG. 13, the embodiments of the present disclosure provide a display apparatus including the display panel according to any of the previous embodiments.

It should be noted that the display apparatus according to the embodiments of the present disclosure has the beneficial effects of the display panel according to any of the previous embodiments, and the reference should be made to the previous description of the beneficial effects of the display panel for the specific, which is not repeated in the embodiments of the present disclosure.

What is claimed is:

1. A display panel, having a first region and a second region, wherein a transmittance of the first region is greater than a transmittance of the second region, and the display panel comprises:
a first pixel unit, arranged in the first region;
at least one first pixel circuit, located in the second region and located on a side of the first region along a second direction, wherein the at least one first pixel circuit is connected to the first pixel unit; and
at least one first signal line, connected to the first pixel circuit corresponding to the first pixel unit, wherein the at least one first signal line comprises a main body segment extending along a first direction, and a first branch and a second branch branched from one end of the main body segment, the first branch is connected to the first pixel circuit, the second branch comprises a first segment arranged in the second region, the first segment and the main body segment are located respectively on two sides of the first region, and the first direction intersects the second direction.

2. The display panel according to claim 1, wherein the second branch further comprises a second segment connected to the first segment and the main body segment, and the first segment and the main body segment are located on two sides of the first region along the first direction.

3. The display panel according to claim 2, further comprising a third pixel circuit as well as a fourth pixel circuit and a plurality of fifth pixel circuits located on two sides of the first region along the first direction, wherein the third pixel circuit is connected to the first segment, the fourth pixel circuit and the plurality of fifth pixel circuits are connected to the main body segment, and the third pixel circuit, the fourth pixel circuit and the fifth pixel circuits are arranged in a line along the first direction.

4. The display panel according to claim 2, wherein the second region surrounds outside of the first region, and a connection point of the main body segment and the first branch is located on a side of the first region along the first direction.

5. The display panel according to claim 4, wherein the first branch comprises a first branch segment extending along the second direction and connected to the main body segment, and a second branch segment extending along the first direction and connected to the first branch segment and the first pixel circuit.

6. The display panel according to claim 4, wherein a connection point of the main body segment and the first branch as well as the first region are located on a same side of the first pixel circuit along the second direction.

7. The display panel according to claim 2, wherein the second segment extends around an outer circumference of the first region.

8. The display panel according to claim 7, wherein the second segment abuts against an edge of the first region.

9. The display panel according to claim 7, wherein the first region is a circular structure, and the second segment comprises an arc-shaped segment; or the first region is a polygonal structure, and the second segment comprises a bending segment.

10. The display panel according to claim 3, wherein the second segment is located within the first region.

11. The display panel according to claim 10, wherein the second segment is a transparent structure, and a material of the second segment comprises at least one of indium tin oxide, indium zinc oxide, silver-doped indium tin oxide, and silver-doped indium zinc oxide.

12. The display panel according to claim 10, wherein the second segment extends along the first direction and passes straight through the first region along the first direction.

13. The display panel according to claim 10, wherein a first virtual extension line extending along the first direction and passing through the first pixel circuit intersects a second virtual extension line extending along the second direction and passing through the third pixel circuit at a virtual intersection point;
a sum of a distance from the first pixel circuit to the virtual intersection point and a distance from the third pixel circuit to the virtual intersection point is greater than a length from the third pixel circuit to the fourth pixel circuit in the second segment; and
a spacing between the first region and the first pixel circuit is not less than 2 mm.

14. The display panel according to claim 2, wherein the at least one first signal line comprises a plurality of first signal lines, and
on a surface perpendicular to a thickness direction of the display panel, orthographic projections of second segments of the plurality of first signal lines at least partially overlap with one another or are arranged side by side along the second direction.

15. The display panel according to claim 1, wherein the at least one first pixel circuit comprises a plurality of first pixel circuits, and a same first signal line is connected to the plurality of first pixel circuits.

16. The display panel according to claim 15, wherein the first signal line comprises a plurality of first branches.

17. The display panel according to claim 1, wherein the first signal line is a data line, a plurality of first pixel circuits are arranged along the second direction and located on at least one side of the data line along the second direction, a connection direction of the first pixel circuit and a corresponding first pixel unit is same as the second direction, and the second direction is a direction where a short side of the display panel extends along; or
the first signal line is a scanning line, a plurality of first pixel circuits are arranged along the second direction and located on at least one side of the scanning line along the second direction, a connection direction of the first pixel circuit and a corresponding first pixel unit is same as the second direction, and the second direction is a direction where a long side of the display panel extends along.

18. The display panel according to claim 1, further comprising:
a second pixel circuit located in the second region and located on a side of the first region along the second direction, wherein the second pixel circuit is connected to the first pixel unit; and
a second signal line connected to the second pixel circuit corresponding to the first pixel unit, wherein the second signal line comprises a third segment and a fourth segment located on two sides of the first region along the first direction, as well as a fifth segment connected to the third segment and the fourth segment, and the fifth segment is connected to the second pixel circuit;
the fifth segment comprises a first sub-segment electrically connected to the second pixel circuit and the fourth segment, and a second sub-segment electrically connected to the second pixel circuit and the third segment.

19. The display panel according to claim 18, wherein the second pixel circuit is located on a side of the first pixel circuit close to the first region;
a spacing between the first region and the second pixel circuit is not greater than 2 mm.

20. A display apparatus, comprising the display panel according to claim 1.
